(19) United States
(12) Patent Application Publication
(10) Pub. No.: US 2015/0245565 A1
(43) Pub. Date: Sep. 3, 2015

(54) Device and Method for Applying Chemicals to Specific Locations on Plants

(71) Applicants: Bob Pilgrim, Benton, KY (US); Harold Shane Sanford, Franklin, TN (US); Clark Duncan, Fulton, KY (US)

(72) Inventors: Bob Pilgrim, Benton, KY (US); Harold Shane Sanford, Franklin, TN (US); Clark Duncan, Fulton, KY (US)

(21) Appl. No.: 14/625,403

(22) Filed: Feb. 18, 2015

Related U.S. Application Data
(60) Provisional application No. 61/942,109, filed on Feb. 20, 2014.

(51) Int. Cl. A01G 7/06; H01L 27/146; B60P 3/30

(52) U.S. Cl. CPC A01G 7/06; B60P 3/30; H01L 27/14621

(57) ABSTRACT

A device and method for applying chemicals to specific plants and parts of plants in natural settings as well as crop fields. In a preferred embodiment, an autonomous vehicle carries the chemical application device and is, in part, controlled by the processing requirements of the machine vision component of the device responsible for detecting and allocating target lists to chemical ejectors that are aimed at these target points as the apparatus is carried through the field or natural environment.

### CROSS-REFERENCE TO RELATED APPLICATIONS

This application claims priority to U.S. Provisional Application No. 61/942,109, filed on Feb. 20, 2014.

### BACKGROUND OF THE INVENTION

The present embodiment relates generally to devices and methods used to distinguish between types of plants, to select and locate and distinguish some plants from a larger collection of plants and surrounding objects, and to apply herbicide or other types of chemicals to individual selected plants as well as to specific parts of plants such as leaves, flowers, fruits, or plant centers while avoiding the application of said chemical to other parts of plants, or to other plants in the immediate region of the targeted plants, or to the surround.

Methods of precision agriculture such as variable-rate spraying and applying multiple types of chemicals in predetermined regions using an application map are known in the art. Imagery collected from earth orbiting satellites, aircraft or other imaging platforms, generally referred to as remote sensing, are analyzed to build geo-referenced chemical application maps. These maps are loaded onto digital storage media and transferred to onboard processors carried on tractors, sprayers, combines and other farm implements. These data are used to control the application of herbicide, fertilizers, fungicides, insecticides and other chemicals in a manner that reduces use of chemicals where they are not needed, and applies said chemicals in higher concentrations where they are needed. In the current art of precision agriculture the scale of controlling application rates is in the range of tens of centimeters to several meters. In other existing precision agricultural application image collection and processing is performed on-board the vehicle supporting variable rate chemical application in real-time.

### BRIEF DESCRIPTION OF THE DRAWINGS

FIG. 1 is a diagram of the chemical application device in a application for row crops.

FIG. 2 is a sequence of images showing the steps in the matching vision procedure for plant segmentation, seed line determination and edge detection.

FIG. 3 is a diagram illustrating the hierarchical decisions in the main loop of the plant target list generation procedure.

FIG. 4 is s cutaway diagram showing the internal components of the chemical ejector.

FIG. 5 is a pictorial sequence showing the steps in the procedure for determining the center of a targeted plant.

FIG. 6 is a diagram illustrating a possible allocation of target points among a number of chemical ejectors.

FIG. 7 is a pictorial view of a multi-band spectral analyzer showing an example application distinguishing soybean plants from cocklebur plants.

FIG. 8 is a perspective view of an autonomous vehicle for carrying the chemical applicator apparatus into the field with a detailed cutaway of the steering/drive wheel assembly.

FIG. 9 is a vertical view of the autonomous vehicle showing three example steering modes possible with the four-wheel steering, four-wheel drive design.

FIG. 10 is a diagram illustrating the operation of the transverse axle with rigid leg structure permitting negotiation of rough terrain while keeping all four wheels in contact with the ground.

FIG. 11 is a illustration of the machine vision-based navigation procedure in row crops.

FIG. 12 is a figure showing the effects of various setting of the F_{dom} factor on the ability to distinguish crop rows under changing lighting conditions.

### SUMMARY OF THE INVENTION

A device and method for the automatic real-time application of chemicals to specific plants and parts of plants in agricultural fields. The invention consists of an image collection device, a processor with machine vision and control software, mechanical actuators for pointing chemical ejectors, a method of pressurization of said chemicals, and high-velocity pulsed ejectors.

### DETAILED DESCRIPTION OF THE INVENTION

The present embodiment for row crops is carried through the field traveling in a direction parallel to the crop row with the centerline of the system aligned with the crop seed line. A sequence of images is collected with a field-of-view of the imaging device covering the seed line and a least half the distance to the adjacent seed lines on either side of the centerline. The images are processed using an onboard processor using machine-vision techniques to distinguish plants from ground clutter and other objects. Locations of plants or plant parts selected for chemical application are identified and localized with respect to the surrounding objects and ground clutter. The size of the target area on the plant is included in the target description so that distribution and amount of chemical to be applied can be determined. As the system moves along the row deviations from constant straight-line motion are determined by monitoring the relative motion of the textured background in the sequence of images being processed.

Target points for application of chemicals are determined as part of a real-time processing method. The target points along with the bounds of the target areas are allocated to the chemical ejectors. Each ejector is responsible for chemical application in a strip of the field running parallel to the crop seed line, covering a width approximately equal to the separation between ejectors with a strip of ground generally centered under each ejector. The limits of coverage for each ejector overlaps the coverage limits of its adjacent ejectors to facilitate allocation of targets in a manner to reduce required slew rates for the actuators that aim the ejectors. The order in which an ejector addresses its target list is determined by a scheduling algorithm the minimizes the amount of motion required by the actuator controlling ejector pointing. In an embodiment, the motion of each controller is limited to a direction perpendicular to the direction of motion of the system so that targets are engaged as the motion of the platform brings them directly under the line of ejectors. The ejectors are pulsed and can fire a single or multiple bursts of chemical to a target, depending on the extent of the target area to be covered. To cover larger target areas the actuator swings the ejector left and right, while rapidly firing a sequence of pulses of chemicals as the platform moves along the crop row.

This chemical application apparatus can be attached to a tractor or other human controlled platform or they can be attached to towed implements. As their operation is modular and self-contained, multiple instances of the apparatus can be distributed along a boom, such as a sprayer boom or other method for allowing simultaneous application to multiple rows of crops. In a preferred embodiment, the apparatus is attached to a lightweight autonomous vehicle capable of traversing the field without human intervention. In this embodiment the speed of the platform can be changed as needed by the chemical applicator to provide additional processing time in dense target environment or to be move more quickly through low target density environments. An advantage realized with a lightweight autonomous vehicle is the ability to enter the field in any weather or soil conditions, which can be critical to addressing the need for timely application of chemicals such as herbicides. For example, the effective control of weeds during the first six weeks of post-emergent crop growth can have as much as a 60% improvement in crop yield.

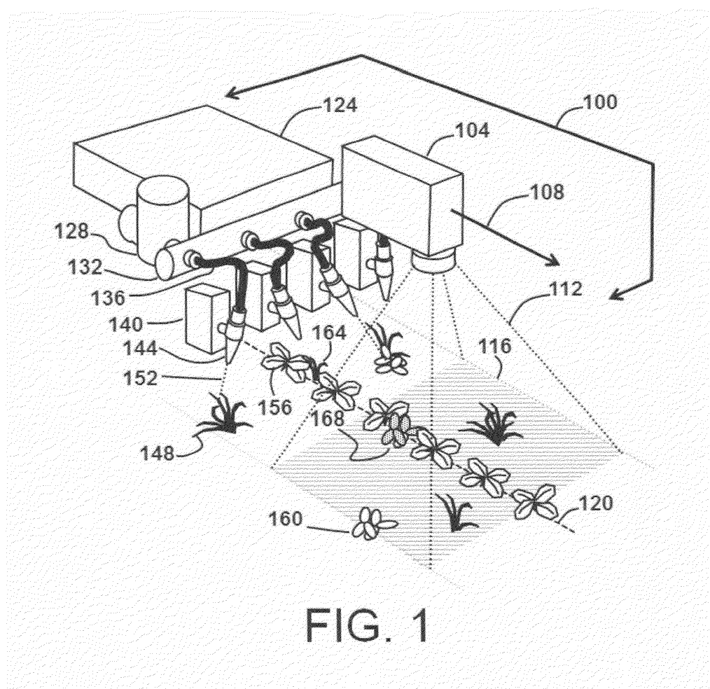

Now referring to the drawings. FIG. 1 shows a diagrammatic overview of the preferred embodiment 100 in use. The imaging device 104 is moved in a direction 108 parallel to the crop row. The field of view of the imaging device 112, projected onto the ground 116 covers a region of length (in the direction of motion) sufficient to record multiple images of plants and to monitor the relative motion of the ground using texture matching. The width of the viewing region is includes at least half the distance to the adjacent rows on either side of the row being processed. The regular occurrence of crop plants in the seed line 120 is used to distinguish the crops from other plants such as weeds. In some embodiments the seed line location is used to navigate the field (autonomous platform), while in other embodiments the seed line location is used to maintain relative alignment of the imaging device with the chemical ejectors.

In an embodiment, the onboard processor 124 is located near the imaging device and the actuators in order to reduce the complexity of the electrical connections and to minimize electrical interference common in the field environment. The processor includes software to implement machine vision operations to detect, locate and identify plant types, to monitor relative motion of platform with respect to ground, generate a target list for chemical application, scheduling software for ordering targets for each ejector, to control the pointing and firing of ejectors, and to control the speed of the carrier platform in the embodiment using an autonomous vehicle.

In order to increase the precision in application of chemicals, the velocity of the ejected chemicals is increased using a staged pressurizing device 128. In some embodiments the pressurized chemical is distributed to all ejectors through a manifold 132 connected to the high-pressure side of the chemical pressurizer. A method to deliver the chemical to the ejectors while still permitting motion of the ejectors themselves is provided through a flexible hose 136 in some embodiments.

In a preferred embodiment, the actuators 140 that point the ejectors are limited to aiming the ejector 144 left and right relative to the direction of motion of the platform. When a target plant 148 appears in the line of fire of the ejector, one or more pulses of chemical 152 are fired at it.

In an embodiment for week management, the chemical being applied is a broad spectrum herbicide such as glyphosate. For the weed control application, target selection can be accomplished using a simple hierarchical algorithm. First it is assumed that the characteristics of the crop plant 156 are known. Plants are selected for herbicide application using a series of criteria. If the plant is not in the seed line 160, then it is considered a weed and is target; if the plant is in the seed line but the leaf shape is different 164, then it is targeted; and if the plant is in the seed line has a similar leaf shape 168 but does not match the regular plant spacing of the crop then it is considered a weed and it targeted. In this case, erroneously targeting the occasional crop plant tends to thin the crop and generally does not affect the overall crop yield.

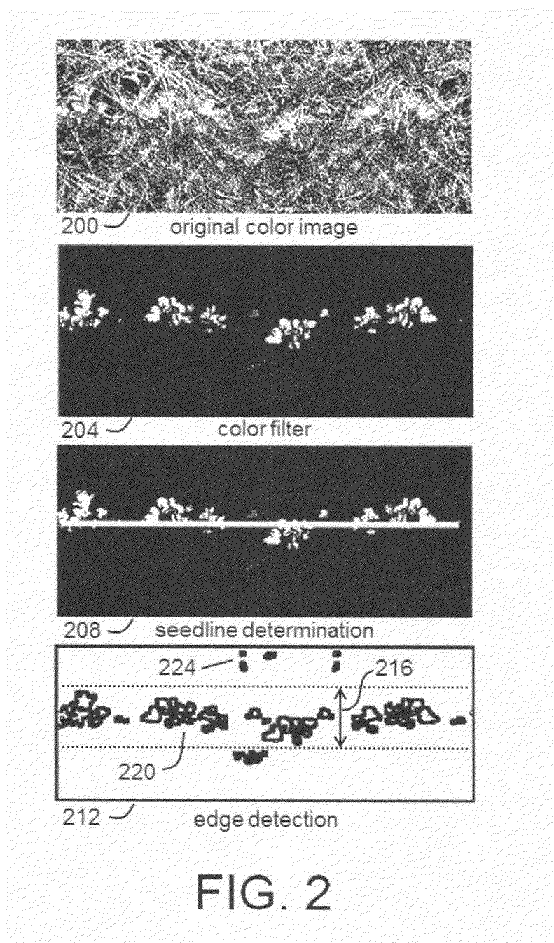

The first task of machine vision processing is segmentation of the living plant material from the background clutter. In FIG. 2 the original image 200 is filtered using a two-part thresholding function based on the normalized values of the image pixels. A pixel is comprised of three components labeled r (red), g (green), and b (blue). These values can be integers in the range 0 to 255 (8-bits) or they can be normalized (0.0 to 1.0). Normalized values are used here. This segmentation filter accepts/rejects pixels using two thresholds T_{dom} for ensuring the dominance of green, and T_{cen} for ensuring that the particular shade of green is centered on the most common green of plants based on the presence of chlorophyll. These two thresholds are defined by

$${T}_{dom} = {F}_{dom} \frac{g}{r + b + 1} {T}_{cen} = {F}_{cen} \frac{\vert r - b \vert}{r + g + b + 1}$$

where F_{dom} and F_{cen} are scaling factors that are determined by the overall light level of the image. Typical values for these factors are F_{dom}=1.5 and F_{cen}=3.6. A pixel is accepted when T_{dom}>1 and T_{cen}<1, otherwise the pixel is rejected. Rejected pixels are set to 0,0,0 RGB value and appear as black in the color filtered image 204. Accepted pixels are left as their original values for texture analysis to determine the location and orientation of the seed line 208. Accepted pixels are converted to 1,1,1 (white) for edge detection 212. Contiguous regions of accepted pixels 220 are interpreted as plants or parts of plants, while very small contiguous regions of accepted pixels 224 are interpreted as noise or clutter.

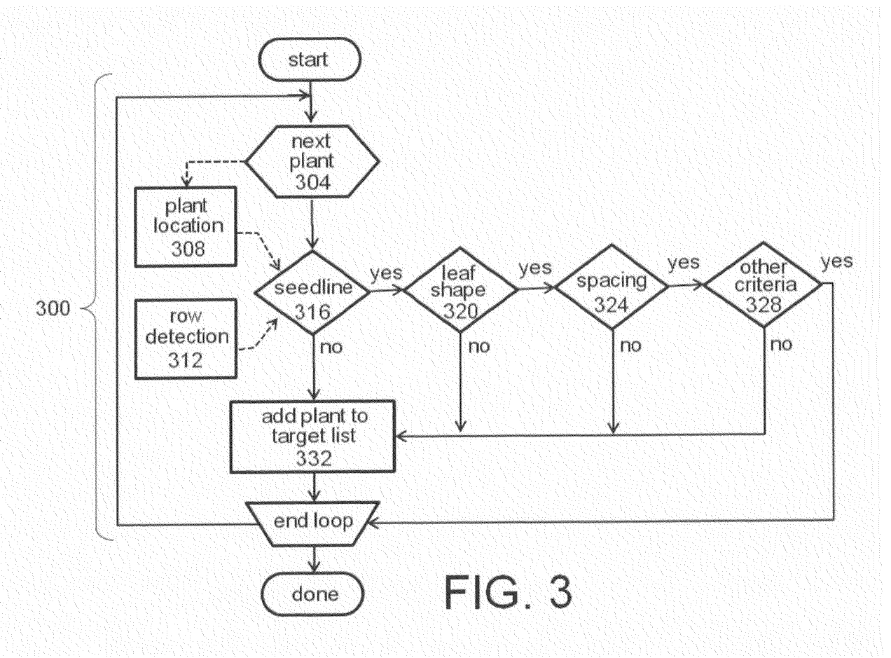

When the individual plants and plant parts have been located and the centerline of the rows (seed line) have been determined a hierarchical classifier procedure depicted in FIG. 3 is used to build a targeted plant list. The main loop of the classifier 300 compares the location 308 of each plant 304 with the position of the row centerline 312. If the plant is beyond a specified distance from the seed line the first conditional 316 returns no (false), the plant is added to the target list 332. If the first conditional returns yes (true) then the second conditional is invoked in which the leaf shape is compared to the standard leaf shape of the crop plant 320. If the plant leaf shape does not match the crop leaf shape the second conditional returns no (false) and the plant is added to the target list. If the plant being tested has a leaf shape that matches the crop plant, the second conditional will return yes (true) and the third conditional will be invoked. In some applications the crop plants are spaced at regular intervals. The third conditional 324 compares the spacing of the test plant to the adjacent plants in the seed line with the standard (or average) spacing of the crop plants which can be input or calculated from the images themselves. If the test plant spacing is substantially less than the standard crop plant spacing the third conditional returns no (false) and the plant is added to the target list. If the spacing is close to the standard spacing then other conditional tests 328, if any, are invoked. If the test plant passes all conditionals then it is not added to the target list and is, by default, designated as a crop plant. The main advantage of this hierarchical procedure is a significant reduction in computational load compared to other plant classifiers used in the prior art.

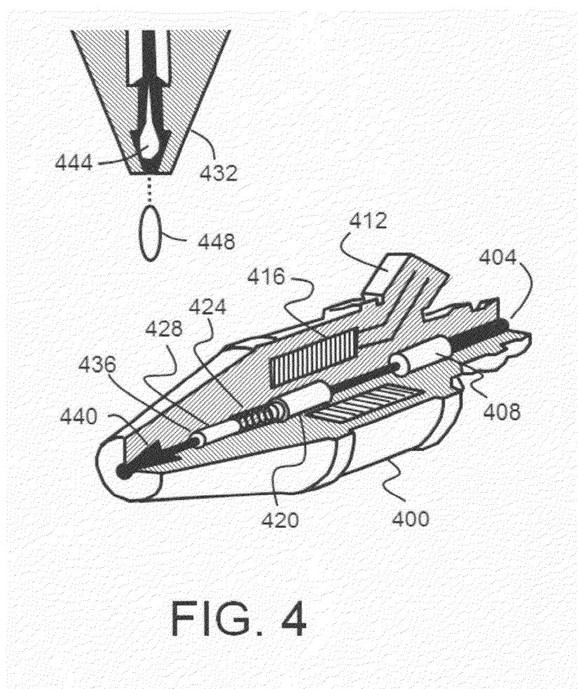

The accuracy of chemical application is improved by increasing the velocity of the chemical coming from the ejector. The chemical ejector depicted in FIG. 4 uses the same principle as a fuel injector. The chemical ejector 400 is comprised of a connector 404 that is attached to a high pressure source of the chemical being applied. At the rear of the ejector housing is a stop 408 for the solenoid piston 420 of the ejector valve. An electrical connection 412 to a solenoid coil 416 is provided for external connection of the control wires. When the coil is charged the solenoid piston 420 is drawn toward the back of the ejector. This permits a small amount of chemical to enter the nozzle of the ejector 440. When the electrical current stops the ejector spring 424 pulls the valve back toward the front of the ejector sealing the access port 436 to the nozzle tip. In a typical application electrical current is applied to the coil in short pulses controlling the amount of chemical being ejected. In a detailed cutaway view of the ejector nozzle tip 432 the shape of the cavity is shown to be an inverted cone in which a small quantity of chemical 444. The pressure of the chemical and the shape of the cavity produce a high-velocity droplet of chemical 448 to be ejected from the tip. For some chemicals, splattering of the chemical can be reduced by adding an adjuvant to control the viscosity of the chemical being ejected.

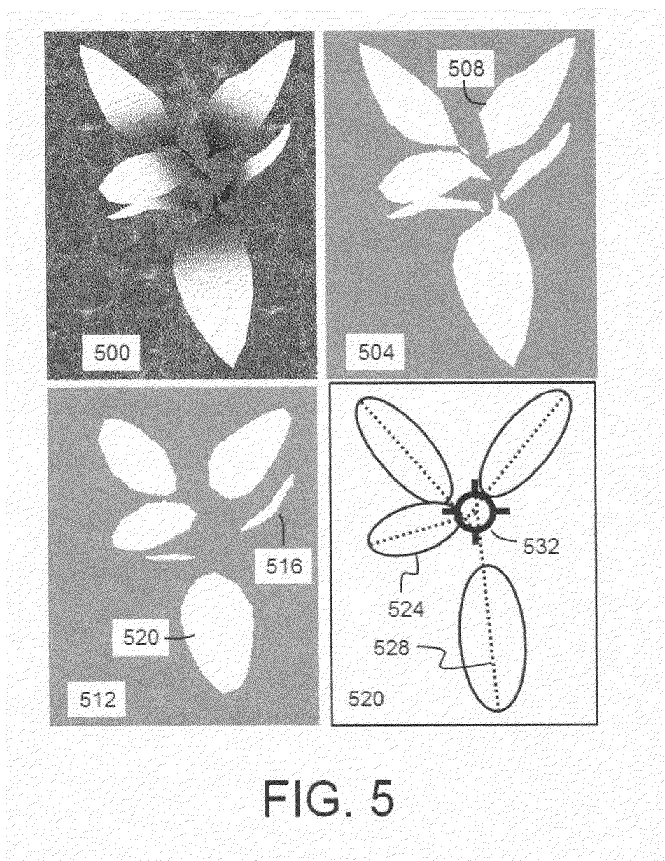

For some plant types and for some applications the target location is the center of a leaf. For other plants and applications it is necessary to choose a target point for chemical application that is at or near the plant center. Some plants have physical structures that place the optimal target position at a location that is not centered on any of its leaves. In FIG. 5 a method for finding the preferred targeting point for these types of plants is depicted. The original image of the plant 300 shows that plant leaves that are elongated and radiate outward from the center. Using the aforementioned RGB color image segmentation method the plant leaves are separated from the background clutter 504. A characteristic leaf of interest is shown 508 in which the shape of the leaf is roughly elliptical. The background clutter, shown in gray pattern in 504 are set to 0,0,0 (zero) by the segmentation method. In order to better isolate the plant leaves an erode method is applied multiple times on the image 512. The erode method sets any pixels that are adjacent to a zero pixels to zero. This tends to separate leaves by reducing their sizes, while eliminating the smaller and thinner plant regions that may have passed the segmentation filter.

Other plant regions may be small enough 516 to be dropped from further processing. What remains is a collection of plant regions that are roughly elliptical 520. A method, such a principle components analysis is used 520 to determine the best fit ellipse for each of the remaining plant regions 524. The major axis 529 of each of the ellipses are computed and finally the closest point of intersection 532 is designated as the preferred targeting point. When the leaves of multiple plants are processing in this manner the corresponding ellipse major axes tend to cluster on the various plant centers, which are the preferred targeting points for chemicals such as broad spectrum herbicide and fertilizers.

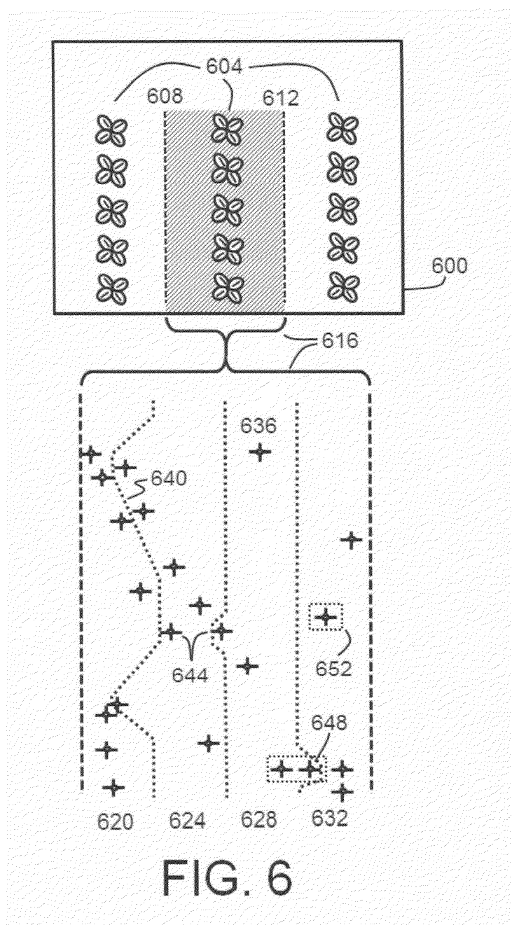

As the list of targeting points are collected they are allocated to specific chemical ejectors as illustrated in FIG. 6. In a row crop 600 the rows 604 are spaced evenly throughout the field. The region of interest for a particular row is bounded by the halfway points 608, 612 between the adjacent rows. We now consider the bounded region for one row 616 in more detail. The targeting regions of individual ejectors are centered directly under the strip of ground closest to the line of travel of each ejector 620, 624, 628, 632. Ideally targeting points would be isolated in each ejector regions 636, however this is not always the case. The actuators can aim the ejectors at plants in a region that overlaps the strips of the adjacent ejectors 540. This is important for the scheduling method which assigns target to maximize the time between firings for each ejector while attempting to minimize the amount of movement required by the actuator. For example two target points 644 could be inside the region of one ejector but position so that they reach the ejector at the same time. In this case, one of the targets can be allocated to an adjacent ejector if it is available and it actuator has sufficient time to aim the ejector. As described previously, some targets are larger in area 652 and require multiple pulses of chemical. In these cases the ejector is pointed left and right rapidly over the targeting region while the ejector is pulsed at a high rate. It Sometimes targets are positioned so that both ejectors that could aim at it are busy with other nearby targets 648. In these situations, the target is combined with a nearby target and treated as a single target of larger area.

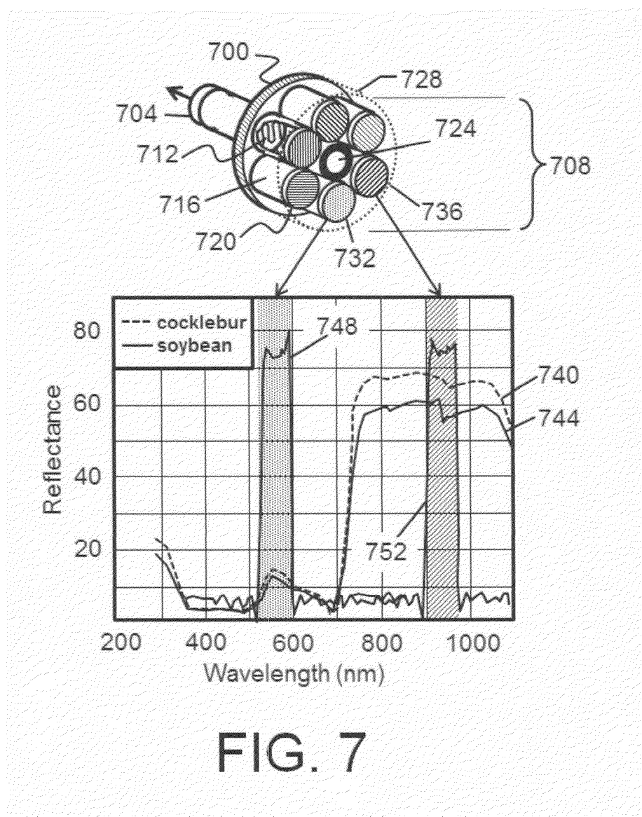

A method and device is shown in FIG. 7 that is an example of implementation of other criteria 328 depicted in the hierarchical target detection procedure of FIG. 3. In some embodiments there is a need and an opportunity for further differentiation of plant types than can be deduced from plant location and leaf shape alone. The differing spectral properties of plants are known in the art, but standard spectral measurement requires large and expensive laboratory equipment not suitable for field use or for real-time processing. A small self-contained multi-spectral discriminator device 700 is presented. This device can be attached as an end effector to a mechanical arm or other pointing method that can place the device on or near plant material being tested. This attachment point 704 is equipped with a method to transfer signals from the device to a processor. The device is comprised of multiple photocells 708, each housed in an opaque container 716 with an aperture over which a band pass filter 720 is placed. Rather than collecting a complete spectrogram, the filters are designed to collect data in specific spectral bands pertinent to plant identification. The spectral characteristics of natural lighting in the field can vary with weather and the light reflected off nearby objects. To reduce this uncertainty, the device can be provided its own light source 724 and its band pass detectors can be housed in a light shield 728 with an open end that can be placed on or near the test plant. As an example of the operation of this device, soybean leaves can be distinguished from cocklebur leaves by comparing the ratios of reflectance in two spectral bands. The spectrogram of cocklebur 740 has a different relative reflectance in the upper and lower half of the 200-1000 nm spectrum than the spectrogram of soybean 744. One band pass filter 732 is fabricated to accept light energy in the 520-600 nm spectral band 748 B₁, while another band pass filter 736 is fabricated to accept light energy in the 900-970 nm spectral band 752 B₂.

$${R}_{t} = \frac{( {B}_{2} - {B}_{1} )}{( {B}_{1} + {B}_{2} )}$$

The ratio of the difference in these two bands to the sum of the same bands results in a relative reflectance Rₜ which can be used as a discriminator for the two plants types. There are a wide variety of spectral methods that can be implemented using this device and method by first determining a set of spectral bands pertinent to the application and then fabricating corresponding band pass filters.

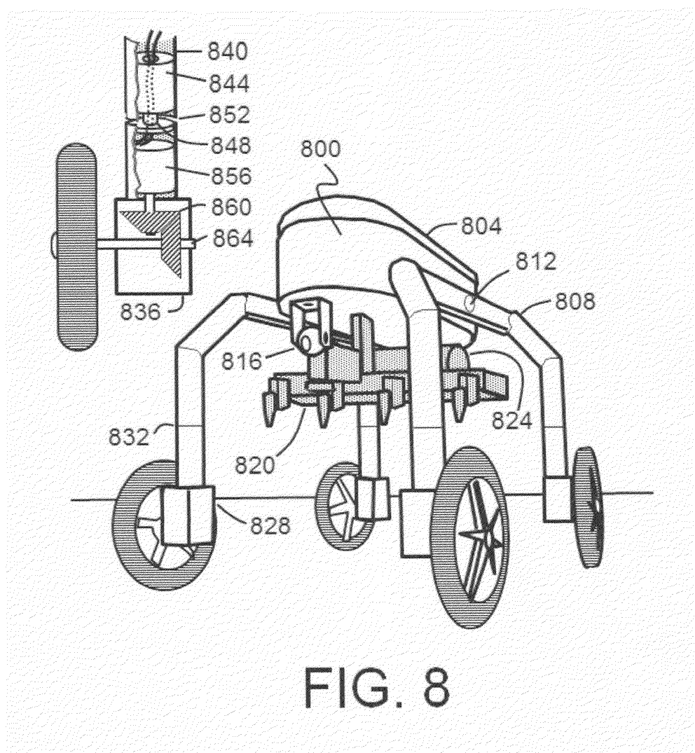

In the preferred embodiment the chemical applicator is carried by an autonomous vehicle, an example of which is depicted in FIG. 8. Some of the components of the chemical application apparatus may be carried inside a body 800 accessible through a cover 804 which provides protection from the weather, dust and other sources of contamination is the field environment. The depicted autonomous vehicle has notable design features that provide for improved traction and maneuverability and advance the art. Specifically, the drive wheels on either side of the vehicle are attached to rigid frames 808 so that the distance between the centers of the wheels on a side of the vehicle are fixed. The frame on the left side of the vehicle is coupled to the frame on the right side of the vehicle with a axle 812 passing through the vehicle body, permitting the left-hand frame to pivot with respect to the right-hand frame allowing all four wheels to remain in contact with the ground in rough terrain. The vehicle is equipped with its own navigation camera 816 which enables it to follow the crop rows. The chemical ejector module 820 is suspended underneath the vehicle providing clear access to the crop plants as the vehicle moves along the row. In some applications the chemical container(s) 824 can be attached to the ejector module itself or it can be embedded in the access hatch 804. Each of the wheels of the vehicle 828 provides steering as well as drive power. The ends of each leg has a point at which the wheel assembly turns 832. In the diagram of a wheel assembly 836 the details of the steering and drive mechanisms is shown. The upper segment of the leg 840 holds the steering motor 844, the drive shaft of which is attached to a disk that turns with the lower segment of the wheel assembly 852. The power cables and control wires for the lower segment pass through the hollow center 848 of the drive shaft of the upper motor. The drive motor 856 resides in the lower segment of the leg assembly. The drive train uses right-angle gears 860 to transfer the drive power to the wheel shaft 864. As shown, this wheel assembly provides the capability for full 360 degrees of rotation of each wheel. In this embodiment the vehicle is provided with four-wheel steering and four-wheel drive.

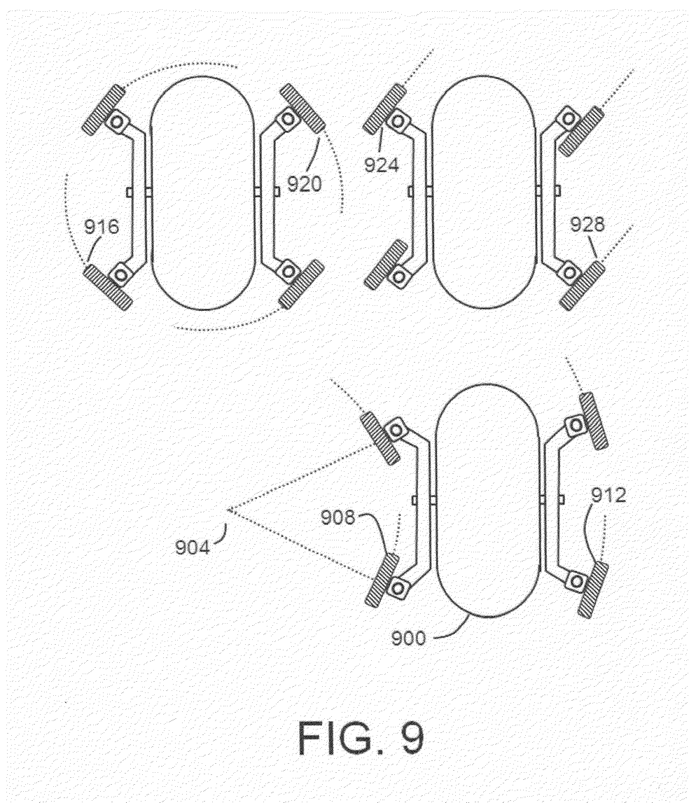

The maneuverability of the vehicle is shown in FIG. 9 illustrating three important steering modes. The steering motors of the vehicle can orient each wheel on the circumference of a circle 916, 920 and each drive motor can be run in either the clockwise or counter-clockwise direction to produce a zero-radius turn to the left or the right. Alternatively all the wheels can be stored to point in the same direction 924, 928 while left-hand drive wheels are turned in one direction and right-hand drive wheels turned in the opposite direction resulting in a straight-line motion in any direction desired. Other steering modes are possible such as turning about a particular point 904. The wheels on one side of the vehicle 908 are steered to match one turning radius while the wheels on the other side of the vehicle 912 are steered to match another turning radius, with both turning radii centers matching to center of the turning point 904. This steering mode is commonly referred to in the art as Ackermann steering named after its inventor. The ability to adjust the steering of each wheel provides an advance that minimizes slippage of each wheel on uneven ground.

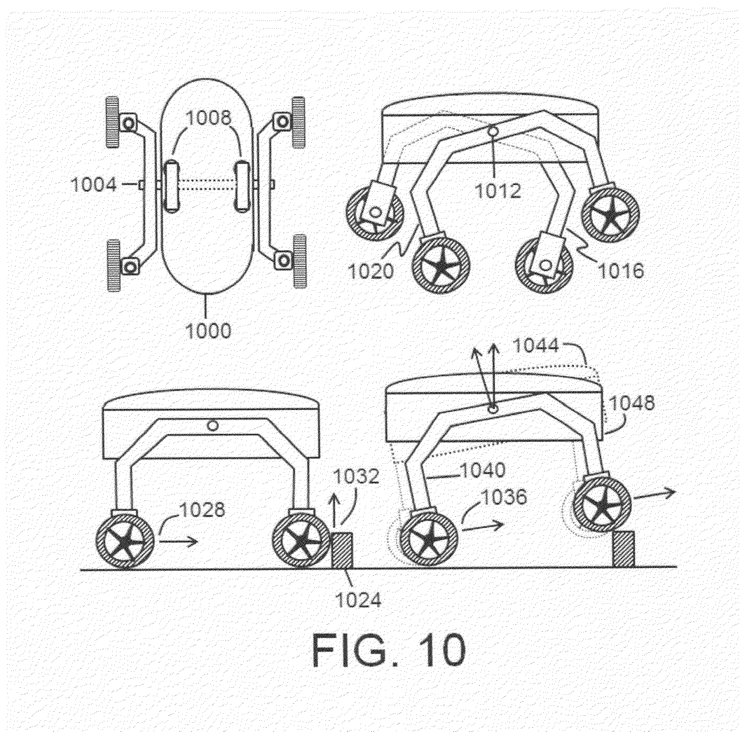

Details of the rigid frame transverse axle design of the vehicle are depicted in FIG. 10. The vehicle body 1000 is suspended on a transverse axle 1004 on the two rigid leg structures on either side of the vehicle. Depending on the application the body of the vehicle can be held level using either passive or active leveling mechanisms 1008. The pivot point 1012 at which the left-side and right-side leg assemblies 1016, 1020 are at the center of point of the length of the vehicle body and is high enough on the side of the body to be stable. When the vehicle encounters an obstacle 1024 the rear drive wheel 1028 pushes the front drive wheel forward increasing the contact pressure against the obstacle increasing friction sufficiently to allow the front drive wheel to lift the vehicle 1032. When the front wheel surmounts the obstacle the rear wheel begins to move the vehicle forward 1036. This is made possible by the rigid leg structure 1040 that ensures that the distance between the centers of rotation of the front wheel and the rear wheel are constant. While one side of the vehicle is negotiating an obstacle the other leg structure on the other side pivots maintaining contact with the ground of all four wheels at all times. In some applications the vehicle body can be rotated from its tilted orientation 1044 back to level 1048 supporting the operation of the chemical applicator or other payload on the vehicle.

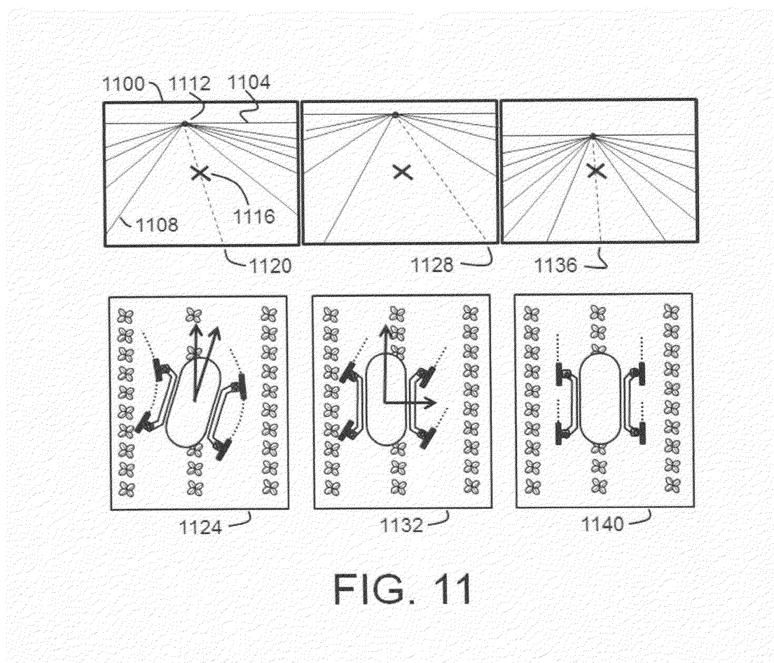

In a preferred embodiment, the autonomous vehicle can use the geographical positioning system (GPS) to stay in the field, but it is not economically viable to provide a GPS receiver of sufficient precision to plant or navigate the rows of an agricultural field. Instead a method of image-based row navigation is used as illustrated in FIG. 11. The navigation system uses the aforementioned RGB segmentation method of define the crop rows. Images 1100 from the navigation camera are processed to determine the locations of the horizon line 1104 and lines representing the location and orientation of the crop rows 1108. The crop row lines converge at the vanishing point 1112 of the perspective views generated by the navigation camera. The central pixel of the navigation camera image 1116 is compared to the line representing the row being followed 1120 by the autonomous vehicle. If the line of the row being followed coincides with the central point but it is not vertical, then a steering mode 1124 is invoked that turns the vehicle to make is parallel to the row. If the row being followed 1128 is not aligned with the central point but the central point is directly below the vanishing point then a steering mode is invoked 1132 that shifts the vehicle to place it over the row. When the central point of the image is directly beneath the vanishing point and the line of the row being followed 1136 is vertical and passes through the central point of the image, then the vehicle is properly aligned with the row and is driven forward.

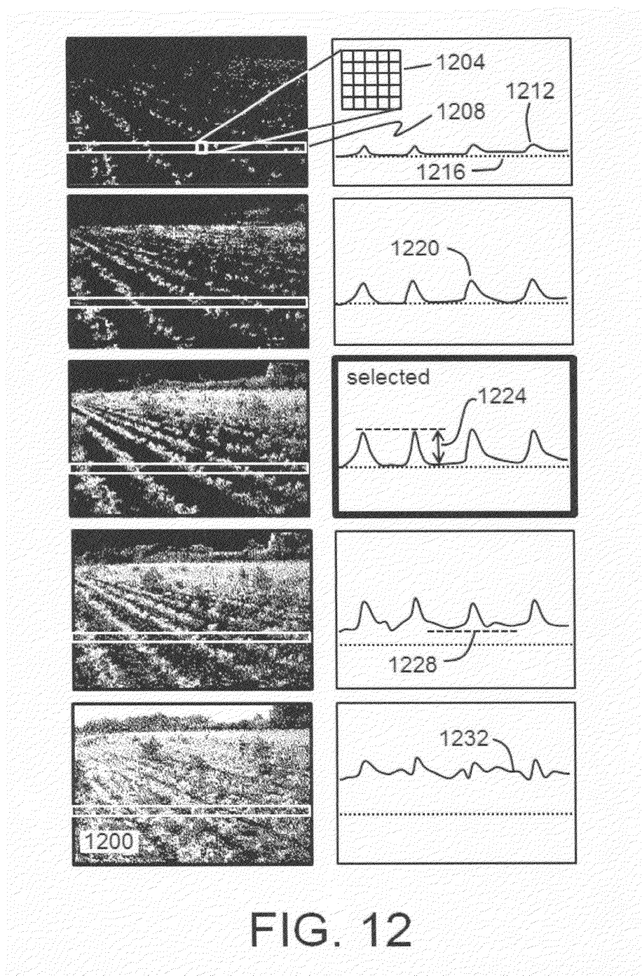

Due to changes in light levels a method is used to adjust the parameters of the segmentation in order to optimize row detection. FIG. 12 illustrates an adaptive method for row detection. The original color images 1200 being collected by the navigation camera are processed using the aforementioned RGB segmentation filter. In this case the F_{dom} factor is varied from a value that rejects most pixels to a value that accepts most pixels. Along the way the average (or sum) of pixel values in an N×N region of pixels 1204 is collected from a horizontal strip 1208 along the image. This strip can be in at any height and angle that supports the particular application. In this example the strip is about ¼ of the distance from the bottom of the image. A curve is generated 1212 of the variation of the average (or sum) pixel values along this horizontal strip. These data are compared to the average baseline 1216. The peak values 1220 of this curve increase with respect to the baseline as the value of F_{dom} is changed. For some value of F_{dom} the amplitude of the peaks 1224 are a maximum. Continuing to change the value of F_{dom} begins to raise the minimum value of the curve 1228 with respect to the original baseline, until all pixels are accepted and the curve 1232 is just a representation of the average pixel values in the strip. The value of F_{dom} is selected to maximize the peak to valley variations with gives the best detection of crop rows. This adaptive test is repeated as needed which can be determined when the overall light levels in the navigation camera images changes more than a specified amount.

In summary the various embodiments of the inventive system provide for precise application of chemicals to specific plants or parts of plants in natural environments, as well as fields of crops. The chemical application apparatus can be attached to human powered conveyances, such a sprayer booms or towed using a tractor. In a preferred embodiment the apparatus is carried by an small, lightweight autonomous vehicle capable of navigating using visual cues. The precision of chemical application is improved in this embodiment by allowing the speed of the platform to be controlled by the targeting procedure of the apparatus. The lightweight platform permits time-critical application of chemicals such as herbicides in fields conditions that do not permit access by larger human-powered conveyances. The balance of electrical, mechanical, and processing methods described herein achieve a cost/performance threshold that achieves a commercially viable solution to a variety of practical problems in precision agriculture.

What is claimed is

1. An apparatus, comprising:
an imaging device for collecting digital images;
a computer processor;
software for segmenting plants and parts of plants from other objects in the images;
software for classifying for chemical application;
software for determining the centers of plants with radiating leaf structures;
software for scheduling the order of engagement of target points by ejectors;
software for controlling actuators;
a device for pressurizing the chemicals;
a means of distributing said chemicals to ejectors without inhibiting ejector motion;
actuators for aiming ejectors at targeted plants;
ejectors for applying one or more doses of chemical at high velocity to a specific target point; and
a means of carrying the apparatus through the field or natural environment.

2. The apparatus of claim 1, wherein the locations of plants are determined by stereoscopic imaging.

3. The apparatus of claim 1, wherein the precision of location and orientation of plants and plants parts are enhanced through the use of artificial light of different colors projected onto plants from different angles.

4. The apparatus of claim 1, wherein part or all of the software is embedded into firmware such as programmable read-only memories or field programmable gate arrays.

5. The apparatus of claim 1, wherein the pressurizing device is integrated as part of each ejector.

6. The apparatus of claim 1, wherein the means of distributing chemicals to ejectors is through the shaft of the actuator.

7. The apparatus of claim 1, wherein the actuators can aim the chemical ejectors in directions both transverse and parallel to the motion of the carrier of the apparatus.

8. A device comprising:
a housing with a means of attachment to a mechanical pointing method;
a multiplicity of sensors comprised of a photocell a band bass filter and the necessary supporting electronics;
a calibrated light source;
a shroud to block natural light;
electronics for encoding sensor signals; and
a connector for transferring power to the light source and sensor and the signal from the sensors.

9. The device of claim 8, wherein the band pass filters are interchangeable.

10. The device of claim 8, wherein the band pass filters are tunable.

11. The device of claim 8, wherein the sensors are stationary while the plants under test are moved by the sensors.

12. The device of claim 8, wherein the light is directed to the sensors remotely by imaging or other optical means.

13. The device of claim 8, wherein natural light is used by monitoring and adaptive calibration.

14. A mobile platform comprising:
a payload bay;
a rigid leg structure holding the left-side wheels and the right-side wheels in a fixed position;
an axle connecting the left side and right side leg structures permitting relative motion between them;
four-wheel steering and four-wheel drive modules;
a navigation camera;
adaptive navigation software that can follow the crop rows;
a means of maintain the payload bay in a horizontal orientation while the platform negotiates rough terrain; and
a method for attachment and monitoring of the chemical application apparatus.

15. The mobile platform of claim 14, wherein cables and control wires from the drive motor are passed through the hollow shaft of the steering motor.

16. The mobile platform of claim 14, wherein the navigation camera is the same imaging device as the chemical application imager.

17. The mobile platform of claim 14, wherein natural environments are navigated.

18. The mobile platform of claim 14, wherein residential yards are navigated.

19. The mobile platform of claim 14, wherein golf course greens are navigated.

20. The mobile platform of claim 14, wherein vegetable gardens are navigated.
